(19) United States
(12) Patent Application Publication
(10) Pub. No.: US 2011/0303270 A1
(43) Pub. Date: Dec. 15, 2011

(54) SOLAR CELL STRUCTURE HAVING HIGH PHOTOELECTRIC CONVERSION EFFICIENCY AND METHOD OF MANUFACTURING THE SAME

(75) Inventors: YEE SHYI CHANG, TAIPEI (TW); CHI-JEN LIU, TAIPEI (TW)

(73) Assignee: AN CHING NEW ENERGY MACHINERY & EQUIPMENT CO., LTD., Taipei (TW)

(21) Appl. No.: 13/017,490

(22) Filed: Jan. 31, 2011

(30) Foreign Application Priority Data
Jun. 15, 2010 (TW) 99119478

(51) Int. Cl. H01L 31/0236; H01L 31/20; H01L 31/0352

(52) U.S. Cl. 136/255; 136/256; 438/71; 257/E31.13

(57) ABSTRACT

A solar cell structure having high photoelectric conversion efficiency and method of manufacturing the same, comprising: a substrate; an amorphous silicon layer; a Group III-V polycrystalline semiconductor layer; a transparent conductive layer formed sequentially on said transparent substrate; and a pattern layer formed on a surface of said transparent conductive layer. Incident light is absorbed through said transparent conductive layer, and is guided by said pattern layer horizontally into distributing evenly in said Group III-V polycrystalline semiconductor layer, thus raising photoelectric conversion efficiency of said solar cell structure.

### BACKGROUND OF THE INVENTION

1. Field of the Invention

The present invention relates to a solar cell technology, and in particular to a solar cell structure having high photoelectric conversion efficiency, that is provided with a pattern layer formed on a transparent conductive layer, and is capable of guiding the incident sunlight into a horizontal direction, so as to increase absorption of incident sunlight in raising its photoelectric conversion efficiency.

2. The Prior Arts

From the 20th century to the 21th century, along with the progress and development of science and technology, and the ever increasing Space of industrialization, the demand for more energy is getting increasingly severe, however, the energy sources on Earth are depleting rapidly, and the global energy crisis is approaching, that may become a reality in a not too distant future. Therefore, the research and development of various alternative energy resources are pursued earnestly. Wherein, the solar energy is the most promising one in the development of green energy resources. According to an estimate, each year, the solar energy irradiated from the Sun to the Earth is about one million times of the amount of total energy consumption on Earth. Namely, in case that 1% of solar energy can be fully utilized, and 10% of which can be converted into electrical energy, then the problem of global energy crunch can be solved effectively.

As such, the solar energy industry is striving hard to meet the global energy demand mentioned above. In solar energy electricity generation, solar cells made of semiconductor material are utilized. In a solar cell, photons in sunlight are absorbed by semiconductor material, so as to agitate atoms in giving out electrons to produce a current in driving a circuit to output electricity, hereby converting light energy into electrical energy. Presently, the materials used for various solar cells include: mono-crystalline silicon, polycrystalline silicon, amorphous silicon, Group III-V, and Group II-VI semiconductor materials. Wherein, silicon is the most commonly and widely used materials, since it is the major material for IC semiconductors, and people have accumulated fairly mature experience in the manufacturing and processing of silicon, as such it is a fairly ideal material for solar cell. However, presently, the photoelectric conversion efficiency of solar cell made of silicon crystal is rather insufficient, since the light absorption capability of the material itself is rather limited, and the flat surface of silicon crystal will reflect part of the incident sunlight off in causing energy loss, so that the solar cell is not able to convert light fully into electricity, thus its photoelectrical conversion efficiency is not satisfactory. Therefore, the structure and design of the solar cell of the prior art has much room for improvement.

### SUMMARY OF THE INVENTION

In view of the problems and shortcomings of the prior art, the present invention provides a solar cell structure having high photoelectrical conversion efficiency, so as to overcome the problems and deficiency of the prior art.

A major objective of the present invention is to provide a solar cell structure having high photoelectrical conversion efficiency, that is of low cost, simple structure, and capable of raising light absorption and photoelectrical conversion efficiency.

Another objective of the present invention is to provide a solar cell structure having high photoelectrical conversion efficiency, that is capable of absorbing incident sunlight of different sections of spectrum, utilizing a pattern layer formed on the surface of a transparent conductive layer in guiding the incident sunlight to raise light absorption, no as to solve the problem of reduced light absorption due to reflection and insufficient light transmission, hereby achieving efficient photoelectrical conversion.

In order to achieve the above mentioned objective, the present invention provides a solar cell structure having high photoelectrical conversion efficiency, comprising: a transparent substrate; an amorphous silicon layer; a Group III-V polycrystalline semiconductor layer; and a transparent conductive layer formed in sequence on the transparent substrate; and a pattern layer formed on the surface of the transparent conductive layer, that guides the incident sunlight horizontally into the Group III-V polycrystalline semiconductor layer.

Furthermore, the present invention provides a solar cell manufacturing method, comprising the following steps: providing a transparent substrate; forming an amorphous silicon layer on the transparent substrate; forming a Group III-V polycrystalline semiconductor layer on the amorphous silicon layer; forming a transparent conductive layer on Group III-V polycrystalline semiconductor layer; and forming a pattern layer on the surface of a transparent conductive layer, such that the pattern layer will guide the incident sunlight horizontally into the Group III-V polycrystalline semiconductor layer.

Further scope of the applicability of the present invention will become apparent from the detailed descriptions given hereinafter. However, it should be understood that the detailed descriptions and specific examples, while indicating preferred embodiments of the present invention, are given by way of illustration only, since various changes and modifications within the spirit and scope of the present invention will become apparent to those skilled in the art from this detailed descriptions.

### BRIEF DESCRIPTION OF THE DRAWINGS

The related drawings in connection with the detailed descriptions of the present invention to be made later are described briefly as follows, in which:

FIG. 1 is a perspective view of a solar cell structure having high photoelectrical conversion efficiency according to an embodiment of the present invention;

FIG. 2 is a cross section view of an enlarged portion of solar cell structure having high photoelectrical conversion efficiency of FIG. 1;

FIG. 3 is a cross section view of the solar cell structure having high photoelectrical conversion efficiency according to another embodiment of the present invention;

FIG. 4a is a schematic diagram of a solar cell structure having high photoelectrical conversion efficiency according to the present invention, wherein, the pattern layer is formed of continuous V-shape slots;

FIG. 4b is a schematic diagram of a solar cell structure having high photoelectrical conversion efficiency according to the present invention, wherein, the pattern layer is formed of non-continuous V-shape slots;

FIG. 4c is a schematic diagram of a solar cell structure having high photoelectrical conversion efficiency according to the present invention, wherein, the pattern layer is formed of a ripple-shape; and

FIG. 5 is a flowchart of the steps of a method of manufacturing a solar cell structure having high photoelectrical conversion efficiency according to the present invention.

### DETAILED DESCRIPTION OF THE PREFERRED EMBODIMENT

The purpose, construction, features, functions and advantages of the present invention can be appreciated and understood more thoroughly through the following detailed description with reference to the attached drawings.

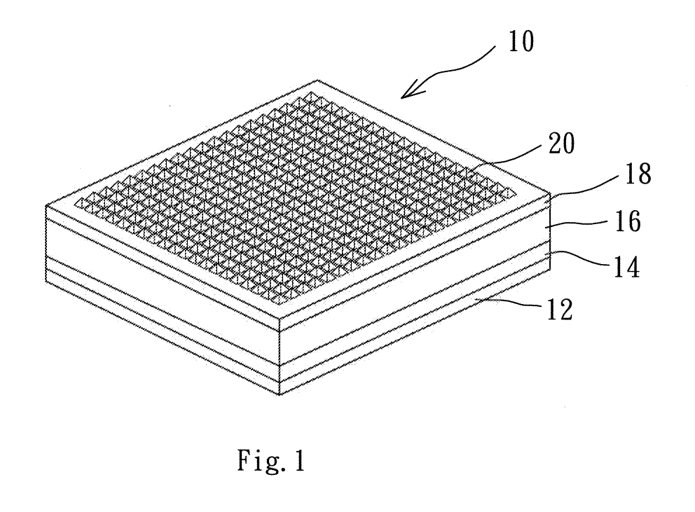

Refer to FIG. 1 for a perspective view of a solar cell structure having high photoelectrical conversion efficiency according to an embodiment of the present invention. As shown in FIG. 1, the solar cell structure 10 of the present invention comprises: a transparent substrate 12, made of glass, quartz, transparent plastic, mono-crystalline Al₂O₃, or flexible transparent materials. On the transparent substrate 12 is stacked from down to top in sequence an amorphous silicon layer 14, a Group III-V polycrystalline semiconductor layer 16, and a transparent conductive layer 18. Wherein, a pattern layer is formed the surface of the transparent conductive layer 18. Herein, a pyramid-shape pattern layer 20 is taken as an example for explanation, such that the transparent conductive layer 18 and the pyramid-shape pattern layer 20 on its surface may be formed simultaneously by means of etching or electrical plating; or, alternatively, a transparent conductive layer 18 is first formed on a Group III-V polycrystalline semiconductor layer 16, then a pyramid-shape pattern layer 20 is formed on the surface of the transparent conductive layer 18 by means of a laser manufacturing process. As such, the pyramid-shape pattern layer 20 will guide the incident sunlight horizontally into the Group III-V polycrystalline semiconductor layer 16, thus increasing effectively the light absorption amount of the Group III-V polycrystalline semiconductor layer 16. The transparent conductive layer 18 is made of transparent conductive oxide (TCO), such as Indium Tin Oxide (ITO), Aluminum Zinc Oxide (AZO), or Zinc Tin Oxide (ZTO). The transparent conductive layer 18 is made through Chemical Vapor Deposition (CVD) process for controlling the crystallization direction of the transparent conductive film, in further controlling the surface appearance of the naturally-formed nm-order texture, and raising light capturing capability and functions of elements, hereby achieving the advantage of lower production cost.

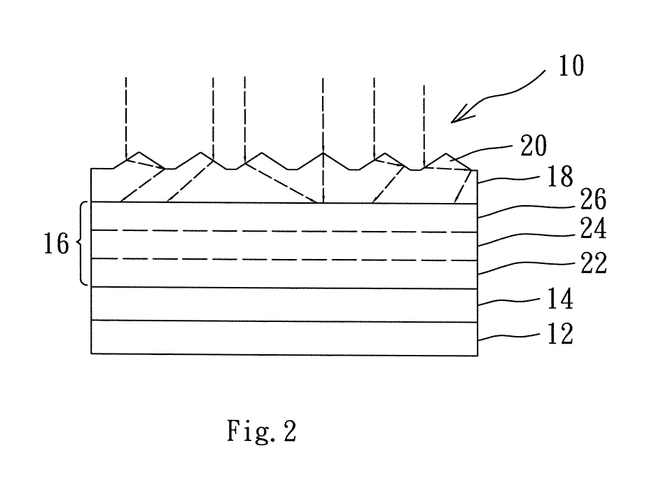

Meanwhile, refer to FIG. 2 for a cross section view of an enlarged portion of solar cell structure having high photoelectrical conversion efficiency of FIG. 1. When sunlight irradiates onto the transparent conductive layer 18, sunlight of longer wavelength is allowed to transmit through the transparent conductive layer 18 having higher light transmittance capability, thus providing characteristics of absorbing wider range of wavelength. As such, through the pyramid-shape pattern layer 20 formed on the surface of the transparent conductive layer 18, sunlight is guided into a horizontal direction, such that not only the light travel route is lengthened, but the light reflection loss can also be reduced.

The Group III-V polycrystalline semiconductor layer 16 receives the sunlight transmitted through the transparent conductive layer 18 and generates electricity. Wherein, the Group III-V polycrystalline semiconductor layer 16 is composed of three layers: a first type semiconductor layer 22, an intrinsic semiconductor layer 24, a second type semiconductor layer 26. In the structure mentioned above, on an amorphous silicon layer 14 is stacked in sequence from down to top the first type semiconductor layer 22, the intrinsic semiconductor layer 24, and the second type semiconductor layer 26. The intrinsic semiconductor layer 24 is an I-type polycrystalline semiconductor, and when the first type semiconductor layer 22 is a P-type semiconductor, then the second type semiconductor layer 26 is an N-type semiconductor; and when the first type semiconductor layer 22 is an N-type semiconductor, then the second type semiconductor layer 26 is a P-type semiconductor. The P-type semiconductor is doped with atoms having three valence electrons, and N-type semiconductor is doped with atoms having five valence electrons, that are used to create an internal electric field. When sunlight incident onto the pyramid-shape pattern layer 20 and travels through the transparent conductive layer 18, then it changes its route and enters into the intrinsic semiconductor layer 24 in creating more electron-hole pairs, and through the internal electric field formed by the P-type semiconductor and N-type semiconductor, carriers are output through the electrode, in realizing photoelectric conversion.

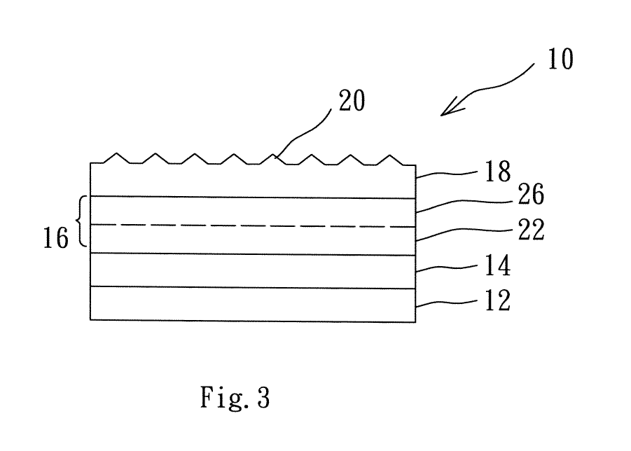

Naturally, in addition to the three-layer structure of the Group III-V polycrystalline semiconductor layer 16 as shown in FIG. 3, the Group III-V polycrystalline semiconductor layer 16 may also be a two-layer structure: a first type semiconductor layer 22 and a second type semiconductor layer 26, and the first type semiconductor layer 22 and the second type semiconductor layer 26 are formed in sequence on the amorphous silicon layer 14. When the first type semiconductor layer 22 is a P-type polycrystalline semiconductor, then the second type semiconductor layer 26 is an N-type polycrystalline semiconductor; and when the first type semiconductor, layer 22 is an N-type polycrystalline semiconductor, then the second type semiconductor layer 26 is a P-type polycrystalline semiconductor. When the incident sunlight enters onto a PN junction formed by an N-type polycrystalline semiconductor and a P-type polycrystalline semiconductor, a portion of electrons will leave the atoms to become free electrons for having enough energy, and the atoms losing the electrons will create holes, and the holes and electrons thus produced will be attracted by P-type semiconductor and N-type semiconductor respectively, thus separating the positive charges and negative charges, and generating potential differences on two sides of the PN junction. When the conductor layer is connected to a circuit, the electrons can pass through and recombine with the holes on the other side of PN junction, hereby generating a current in the circuit, thus the electric energy can be output through for example a conduction wire.

Since the Group III-V polycrystalline semiconductor layer 16 is of a direct energy gap semiconductor, it has better photoelectric conversion efficiency, also since there are numerous types of Group III-V materials, that offer more selections for absorption spectrum and characteristic modulations, also it can be made into thin film to reduce cost significantly, such that the material itself and its photoelectric conversion efficiency are less affected by the thermal effect, and that is helpful in maintaining stability of solar cell operated in the high focusing factor light gathering system, hereby reducing deterioration of material and increasing service life of the solar cell. Furthermore, with the guidance of incident light provided by pyramid-shape pattern layer 20, and the increased transmittance of incident light through the transparent conductive layer 18, thus effectively increasing light absorption of the Group III-V polycrystalline semiconductor layer 16 and raising the photoelectric conversion efficiency.

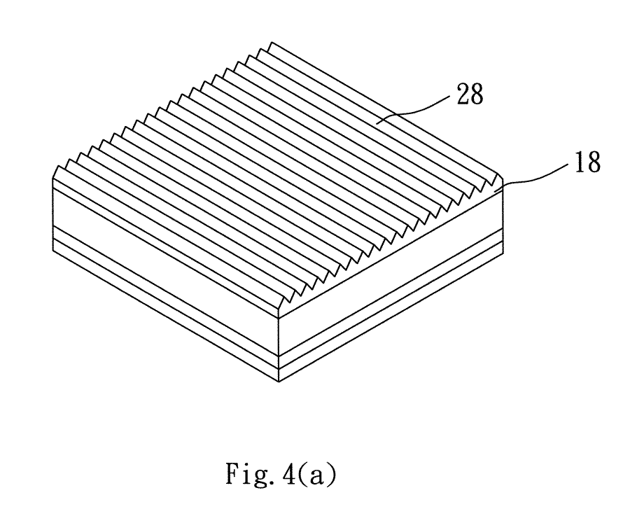

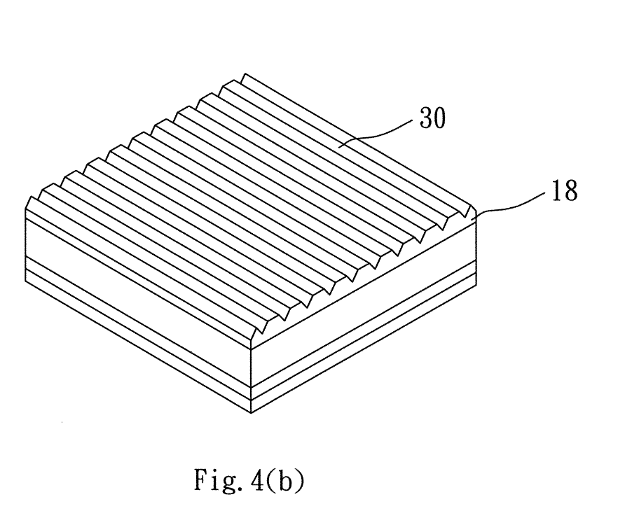

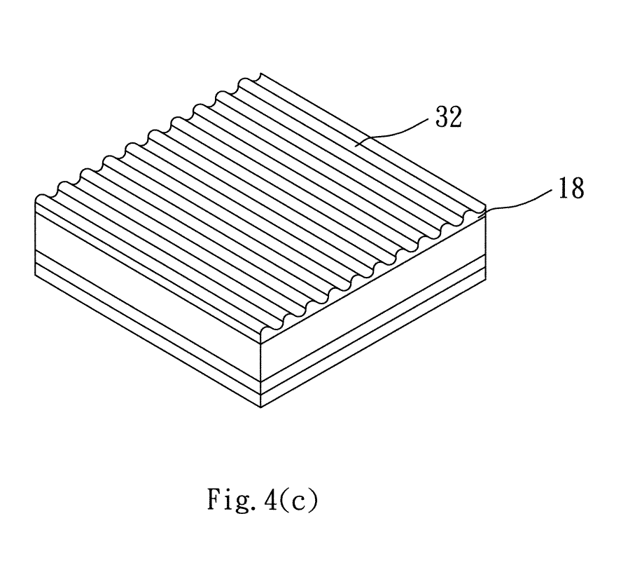

Subsequently, in order to fully utilize the sunlight in an efficient way, a pattern layer can be formed on a surface of the transparent conductive layer 18 by means of laser, electroplating, or etching, such that in addition to the pyramid-shape pattern layer 20, a continuous V-shape slot pattern layer 28 can be formed on the transparent conductive layer 18 as shown in FIG. 4a; a non-continuous V-shape slot pattern layer 30 can be formed on the transparent conductive layer 18 as shown in FIG. 4b; and a ripple-shape pattern layer 32 can be formed on the transparent conductive layer 18 as shown in FIG. 4c. Regardless of the structures of pattern layers mentioned above, they are all capable of guiding the sunlight incident at various angles into horizontal direction to change the route of the light effectively, so that the light travel route is lengthened and light can be distributed evenly in the Group III-V polycrystalline semiconductor layer 16, such that not only light absorption is increased, but the loss due to reflection as caused by direct transmission of incident light can also be avoided, meanwhile the problem of inferior photoelectric conversion efficiency due to insufficient light transmittance can be solved.

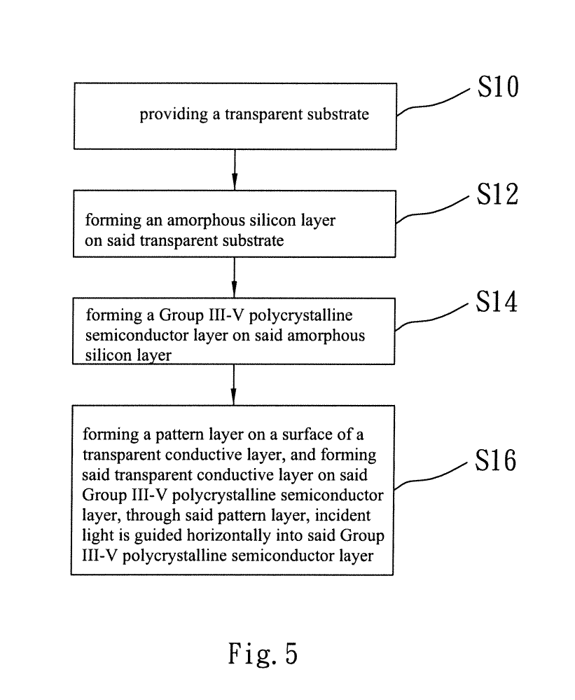

Finally, refer to FIG. 5 for a flowchart of the steps of method of manufacturing a solar cell structure having high photoelectrical conversion efficiency according to the present invention. As shown in FIG. 5, firstly, in step S10, providing a transparent substrate, that can be made of glass, quartz, transparent plastic, mono-crystalline Al₂O₃, or flexible transparent materials, etc. Next, in step S12, forming a layer of amorphous silicon on the transparent substrate through using Plasma Enhanced Chemical Vapor Deposition (PECVD). Then, in step S14, forming a Group III-V polycrystalline semiconductor layer 16 on the amorphous silicon layer by means of Metal Organic Chemical Vapor Deposition (MOCVD) through using the crystal lattice characteristics of the amorphous silicon layer, in this step, firstly, forming a first type semiconductor layer on the amorphous silicon layer, then, forming an intrinsic semiconductor layer on the first type semiconductor layer, and finally, forming a second type semiconductor layer on the intrinsic semiconductor layer. Finally, in step S16, forming a pattern layer on a surface of a transparent conductive layer, then forming the transparent conductive layer having the pattern layer on the Group III-V polycrystalline semiconductor layer, as such, through the pattern layer, such as a pyramid shape, a continuous V-shape slot, a non-continuous V-shape slot, or a ripple-shape pattern layer, the incident sunlight is guided horizontally into and distributed evenly in the Group III-V polycrystalline semiconductor layer 16, hereby effectively raising its photoelectric conversion efficiency.

The above detailed description of the preferred embodiment is intended to describe more clearly the characteristics and spirit of the present invention. However, the preferred embodiments disclosed above are not intended to be any restrictions to the scope of the present invention. Conversely, its purpose is to include the various changes and equivalent arrangements which are within the scope of the appended claims.

What is claimed is:

1. A solar cell structure having high photoelectric conversion efficiency, comprising:
a substrate;
an amorphous silicon layer, disposed on said substrate;
a Group III-V polycrystalline semiconductor layer, disposed on said amorphous silicon layer; and
a transparent conductive layer, provided on said Group III-V polycrystalline semiconductor layer, and a pattern layer is provided on a surface of said transparent conductive layer, for guiding incident light horizontally into said Group III-V polycrystalline semiconductor layer.

2. The solar cell structure having high photoelectric conversion efficiency as claimed in claim 1, wherein said pattern layer is a pyramid shape, a continuous V-shape slot, a non-continuous V-shape slot, or a ripple-shape pattern layer.

3. The solar cell structure having high photoelectric conversion efficiency as claimed in claim 1, wherein said transparent conductive layer is made of transparent conductive oxide (TCO).

4. The solar cell structure having high photoelectric conversion efficiency as claimed in claim 3, wherein said transparent conductive oxide (TCO) is Indium Tin Oxide (ITO), Aluminum Zinc Oxide (AZO), or Zinc Tin Oxide (ZTO).

5. The solar cell structure having high photoelectric conversion efficiency as claimed in claim 1, wherein said Group III-V polycrystalline semiconductor layer includes a first type semiconductor layer, an intrinsic semiconductor layer, and a second type semiconductor layer.

6. The solar cell structure having high photoelectric conversion efficiency as claimed in claim 5, wherein when said first type semiconductor layer is a P-type semiconductor, then said second type semiconductor layer is an N-type semiconductor; and when first type semiconductor layer is said N-type semiconductor, then said second type semiconductor layer is said P-type semiconductor.

7. The solar cell structure having high photoelectric conversion efficiency as claimed in claim 1, wherein said transparent substrate is made of glass, quartz, transparent plastic, mono-crystalline Al₂O₃, or flexible transparent materials.

8. A method of manufacturing a solar cell structure having high photoelectric conversion efficiency, comprising the following steps:
providing a substrate;
forming an amorphous silicon layer on said substrate;
forming a Group III-V polycrystalline semiconductor layer on said amorphous silicon layer; and
forming a pattern layer on a surface of a transparent conductive layer, and depositing said transparent conductive layer on said Group III-V polycrystalline semiconductor layer, such that through said pattern layer, incident light is guided horizontally into said Group III-V polycrystalline semiconductor layer.

9. The method of manufacturing a solar cell structure having high photoelectric conversion efficiency as claimed in claim 8, wherein said pattern layer is a pyramid shape, a continuous V-shape slot, a non-continuous V-shape slot, or a ripple-shape pattern layer.

10. The method of manufacturing a solar cell structure having high photoelectric conversion efficiency as claimed in claim 8, wherein said transparent conductive layer is made of transparent conductive oxide (TCO).

11. The method of manufacturing a solar cell structure having high photoelectric conversion efficiency as claimed in claim 10, wherein said transparent conductive oxide (TCO) is Indium Tin Oxide (ITO), Aluminum Zinc Oxide (AZO), or Zinc Tin Oxide (ZTO).

12. The method of manufacturing a solar cell structure having high photoelectric conversion efficiency as claimed in claim 8, wherein a step of forming said Group III-V polycrystalline semiconductor layer, comprising following steps:
forming a first type semiconductor layer on said amorphous silicon layer;
forming an intrinsic semiconductor layer on said first type semiconductor layer; and
forming a second type semiconductor layer on said intrinsic semiconductor layer.

13. The method of manufacturing a solar cell structure having high photoelectric conversion efficiency as claimed in claim 12, wherein when said first type semiconductor layer is a P-type semiconductor, then said second type semiconductor layer is an N-type semiconductor; and when first type semiconductor layer, is said N-type semiconductor, then said second type semiconductor layer is said P-type semiconductor.

14. The method of manufacturing a solar cell structure having high photoelectric conversion efficiency as claimed in claim 8, wherein said transparent substrate is made of glass, quartz, transparent plastic, mono-crystalline Al₂O₃, or flexible transparent materials.
